(19) United States
(12) Patent Application Publication
(10) Pub. No.: US 2020/0013744 A1
(43) Pub. Date: Jan. 9, 2020

(54) CIRCUIT BOARD ELEMENT AND MANUFACTURING METHOD THEREOF

(71) Applicant: Unimicron Technology Corp., Taoyuan City (TW)

(72) Inventors: Yu-Chung Hsieh, Hsinchu City (TW); Chun-Hsien Chien, Hsinchu City (TW); Yu-Hua Chen, Hsinchu City (TW)

(73) Assignee: Unimicron Technology Corp., Taoyuan City (TW)

(21) Appl. No.: 16/181,374

(22) Filed: Nov. 6, 2018

(30) Foreign Application Priority Data
Jul. 4, 2018 (TW) 107123059

(51) Int. Cl. H01L 23/00; H01L 21/027; H01L 21/768

(52) U.S. Cl. CPC H01L 24/17; H01L 2924/3511; H01L 21/76877; H01L 21/0274

(57) ABSTRACT

A circuit board element including an insulating layer, a circuit layer, a protective layer, a plurality of solder balls, and a dielectric layer is provided. The circuit layer is disposed on the insulating layer. The protective layer is disposed on the circuit layer and has a plurality of openings exposing the circuit layer. The plurality of solder balls are disposed on the protective layer and embedded in the corresponding openings. The dielectric layer is disposed between the solder balls and the protective layer. A manufacturing method of a circuit board element is also provided.

### CROSS-REFERENCE TO RELATED APPLICATION

This application claims the priority benefit of Taiwan application serial no. 107123059, filed on Jul. 4, 2018. The entirety of the above-mentioned patent application is hereby incorporated by reference herein and made a part of this specification.

### BACKGROUND OF THE INVENTION

### Field of the Invention

The disclosure relates to an electronic device and a manufacturing method thereof, and more particularly, to a circuit board element and a manufacturing method thereof.

### Description of Related Art

On a regular circuit board, electrical connection with other electronic elements is often established via solder balls. However, the solder balls may be detached (i.e., so-called drop ball) due to internal stress such as poor soldering and thermal expansion and contraction or external stress. Therefore, how to reduce the probability of solder ball detachment on the circuit board is an urgent issue.

### SUMMARY OF THE INVENTION

The disclosure provides a circuit board element and a manufacturing method thereof having better yield.

The manufacturing method of the circuit board element of the disclosure includes the following steps. A circuit substrate is provided. The circuit substrate includes an insulating layer, a circuit layer, a protective layer, and a plurality of solder balls. The circuit layer is disposed on the insulating layer. The protective layer is disposed on the circuit layer and has a plurality of openings exposing the circuit layer. The solder balls are disposed on the protective layer and embedded in the corresponding openings, and a space is disposed between each of the solder balls and the protective layer. The circuit substrate is disposed on a carrier, and the solder balls are away from the carrier. At least one trench penetrating the circuit substrate is formed to expose the carrier. A photoresist material layer is formed on the circuit substrate to cover the circuit substrate and be filled in the spaces and also be filled in the trench to cover the carrier. A portion of the photoresist material layer filled in the spaces is cured to form a dielectric layer at least between the solder balls and the protective layer. A portion of the photoresist material layer filled in the trench is removed to expose the carrier. The carrier is removed.

In an embodiment of the disclosure, the material of the photoresist material layer includes a photoresist and a filler.

In an embodiment of the disclosure, the material of the photoresist material layer includes a positive photoresist and the manufacturing method further includes the following steps. Before the dielectric layer is formed, an exposure and a developing process is performed on the photoresist material layer to remove a portion of the photoresist material layer not filled in the spaces and expose the solder balls and a portion of the protective layer.

In an embodiment of the disclosure, the material of the photoresist material layer includes a positive photoresist and the manufacturing method further includes the following steps. Before the dielectric layer is formed, an exposure and a developing process is performed on the photoresist material layer to remove a portion of the photoresist material layer not filled in the spaces and expose the solder balls, a portion of the protective layer, and the carrier corresponding to the trench.

In an embodiment of the disclosure, the material of the photoresist material layer includes a positive photoresist and the manufacturing method further includes the following steps. Before the dielectric layer is formed, an exposure and a developing process is performed on the photoresist material layer via a mask to remove a portion of the photoresist material layer and expose the solder balls and a portion of the protective layer. A portion of the photoresist material layer filled in the spaces and covering a sidewall of the trench is cured to form the dielectric layer.

In an embodiment of the disclosure, the mask has a plurality of slits.

In an embodiment of the disclosure, the material of the photoresist material layer includes a negative photoresist and the manufacturing method further includes the following steps. Before the dielectric layer is formed, an anisotropic etching process is performed on the photoresist material layer to remove a portion of the photomask material layer to expose the solder balls and a portion of the protective layer.

In an embodiment of the disclosure, the material of the photoresist material layer includes a negative photoresist and the manufacturing method further includes the following steps. Before the dielectric layer is formed, an anisotropic etching process is performed on the photoresist material layer to remove a portion of the photoresist material layer not filled in the spaces and expose the solder balls and a portion of the protective layer. An exposure process is performed on the photoresist material layer via a mask to cure a portion of the photoresist material layer filled in the spaces to form the dielectric layer.

In an embodiment of the disclosure, the exposure process further cures a portion of the photoresist material layer covering a sidewall of the at least one trench to form the dielectric layer.

In an embodiment of the disclosure, the material of the photoresist material layer includes a negative photoresist and the manufacturing method further includes the following steps. Before the dielectric layer is formed, an anisotropic etching process is performed on the photoresist material layer to remove a portion of the photoresist material layer not filled in the spaces and expose the solder balls and a portion of the protective layer. An exposure process is performed on the photoresist material layer to cure a portion of the photoresist material layer filled in the spaces and filled in the at least one trench. A portion of the cured photoresist material layer filled in the at least one trench is removed to form the dielectric layer.

In an embodiment of the disclosure, the method of removing a portion of the cured photoresist material layer filled in the at least one trench includes cutting.

The disclosure provides a circuit board element including an insulating layer, a circuit layer, a protective layer, a plurality of solder balls, and a dielectric layer. The circuit layer is disposed on the insulating layer. The protective layer is disposed on the circuit layer and has a plurality of openings exposing the circuit layer. The plurality of solder balls are disposed on the protective layer and embedded in the corresponding openings. The dielectric layer is disposed between the solder balls and the protective layer.

In an embodiment of the disclosure, the insulating layer includes a core layer.

In an embodiment of the disclosure, the material of the core layer is different from the material of the protective layer and the dielectric layer, and the material of the core layer includes a polymer glass fiber composite substrate, a glass substrate, a ceramic substrate, an insulating silicon substrate, or a polyimide glass fiber composite substrate.

In an embodiment of the disclosure, the material of the dielectric layer includes a photoimageable dielectric.

In an embodiment of the disclosure, the material of the dielectric layer further includes a filler.

In an embodiment of the disclosure, an orthographic projection of the dielectric layer on the protective layer is overlapped within an orthographic projection of the solder balls on the protective layer.

In an embodiment of the disclosure, an edge of the dielectric layer is aligned with an edge of the solder balls.

In an embodiment of the disclosure, the dielectric layer further covers a sidewall of the insulating layer and a sidewall of the protective layer.

In an embodiment of the disclosure, the solder balls include a plurality of first solder balls and a plurality of second solder balls, a size of the first solder balls is greater than a size of the second solder balls, and a size of the dielectric layer between the first solder balls and the protective layer is greater than a size of the dielectric layer between the second solder balls and the protective layer.

Based on the above, in the disclosure, a dielectric layer is formed between the solder balls and the protective layer by photoresist. The dielectric layer between the solder balls and the protective layer may be directly in contact with a curved bottom surface of a spherical top of the solder balls to support or fix the spherical top of the solder balls. In other words, the dielectric layer between the solder balls and the protective layer may also be referred to as a dielectric block surrounding a base of the solder balls to achieve the effect of supporting and protecting the solder balls. Therefore, the probability of solder ball detachment may be reduced such that the yield of the circuit board element may be improved. Moreover, even if the plurality of solder balls have different sizes, the dielectric layers between the protective layer and the solder balls of different sizes can have different sizes by the manufacturing method of the disclosure. As a result, even if the plurality of solder balls have different sizes, the probability of detachment of the plurality of solder balls may be reduced via the corresponding dielectric layer, and electrical connection with other electronic elements is not affected by the dielectric layers having the same size or height between solder balls having different sizes and the protective layer.

In order to make the aforementioned features and advantages of the disclosure more comprehensible, embodiments accompanied with figures are described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1A to FIG. 1K are cross-sectional views of a manufacturing method of a circuit board element according to a first embodiment of the invention.

FIG. 2A to FIG. 2D are cross-sectional views of a portion of a manufacturing method of a circuit board element according to a second embodiment of the invention.

FIG. 3A to FIG. 3H are cross-sectional views of a portion of a manufacturing method of a circuit board element according to a third embodiment of the invention.

FIG. 4A to FIG. 4C are cross-sectional views of a portion of a manufacturing method of a circuit board element according to a fourth embodiment of the invention.

FIG. 5A to FIG. 5C are cross-sectional views of a portion of a manufacturing method of a circuit board element according to a fifth embodiment of the invention.

### DESCRIPTION OF THE EMBODIMENTS

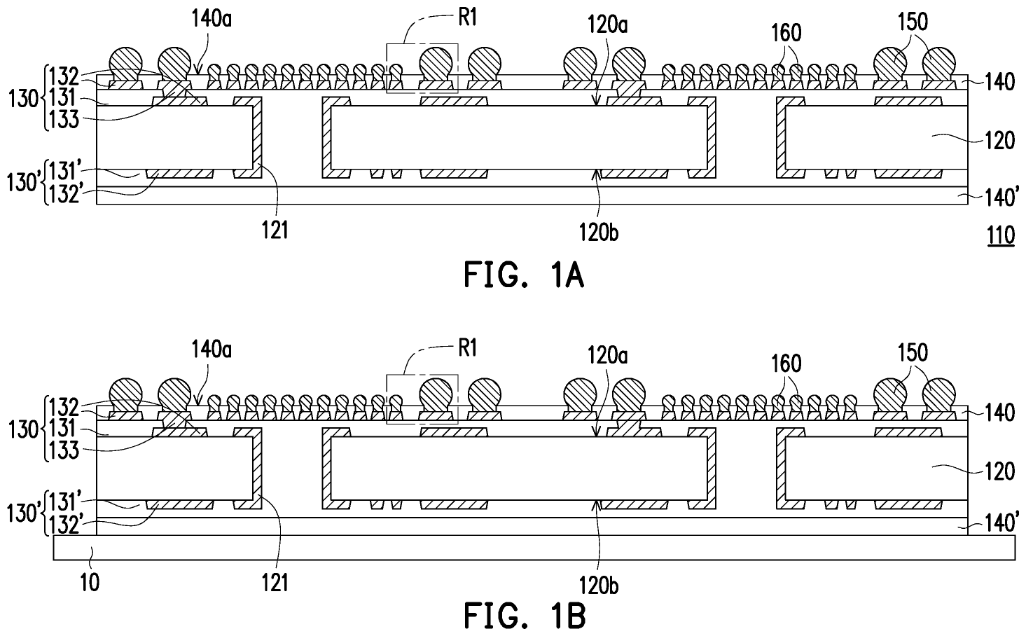

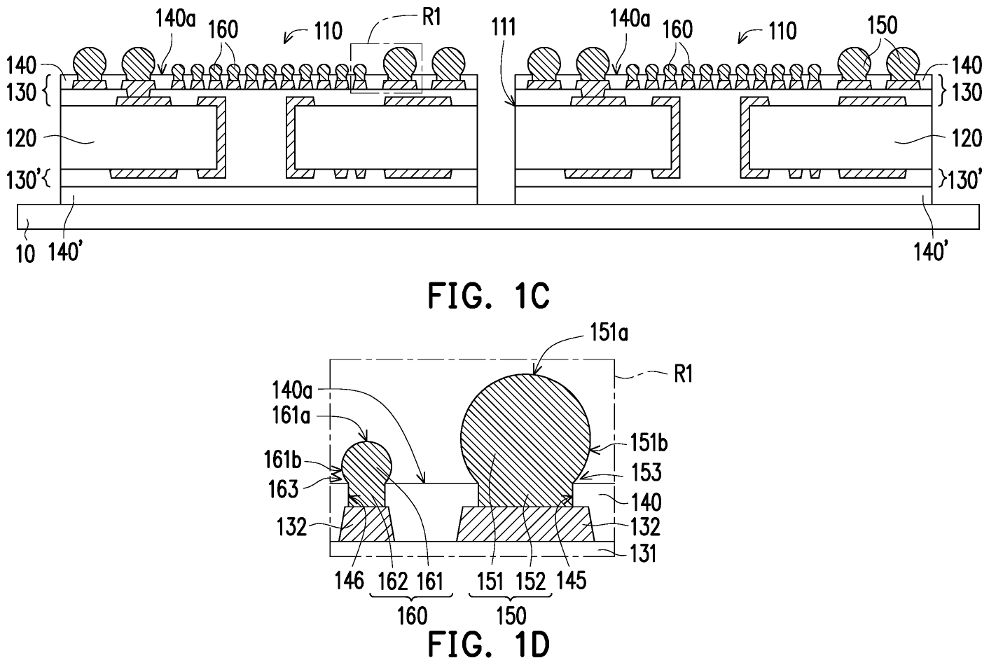

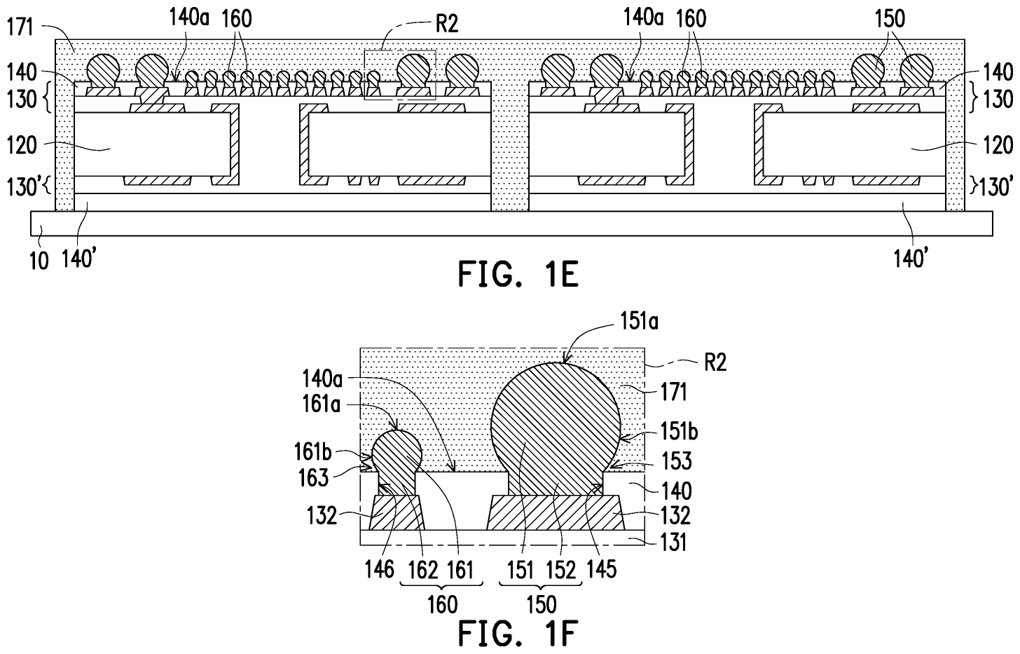

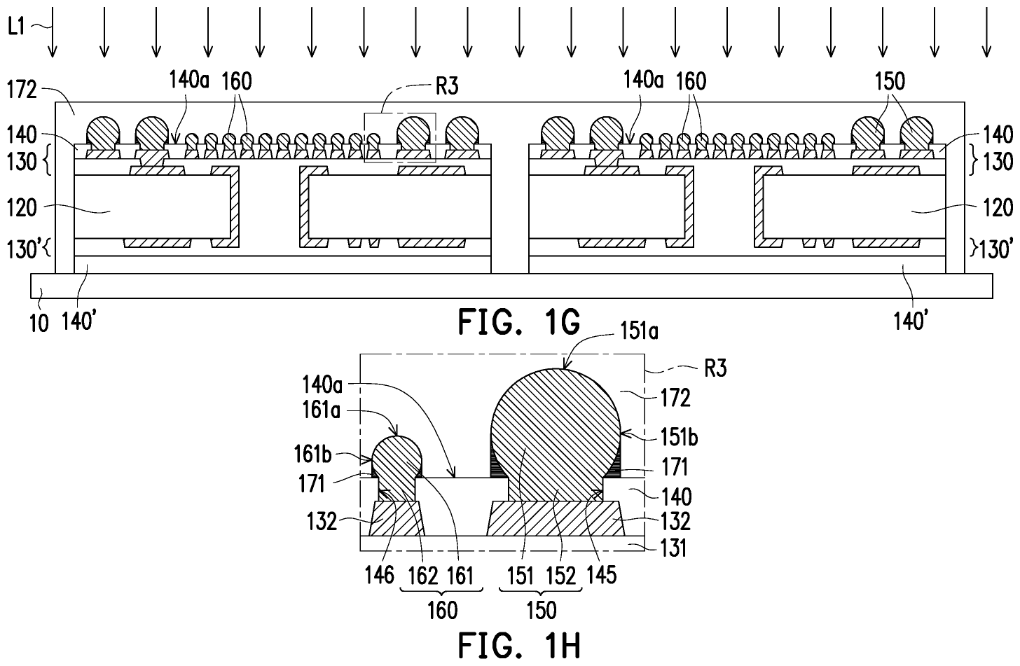

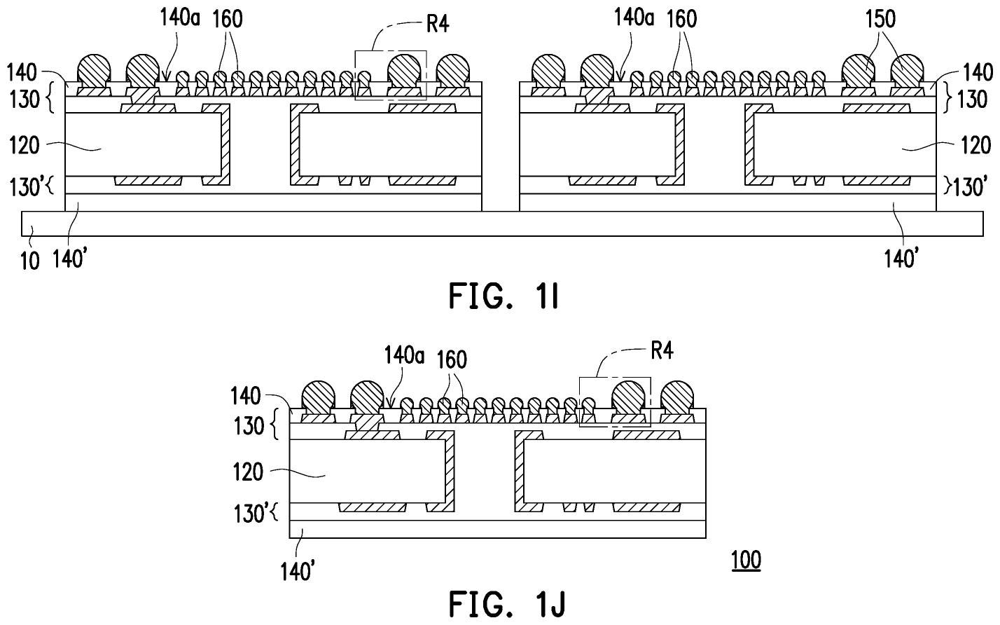

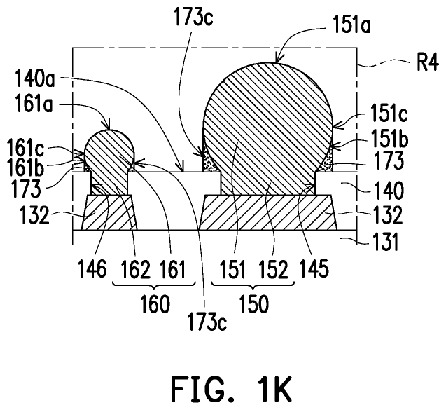

FIG. 1A to FIG. 1I are cross-sectional views of a manufacturing method of a circuit board element according to a first embodiment of the invention. FIG. 1D may be an enlarged view of region R1 in FIG. 1A, FIG. 1B, or FIG. 1C. FIG. 1F may be an enlarged view of region R2 in FIG. 1E. FIG. 1H may be an enlarged view of region R3 in FIG. 1G. FIG. 1K may be an enlarged view of region R4 in FIG. 1I or FIG. 1J.

The manufacturing method of the circuit board structure of the present embodiment includes the following steps. First, referring to FIG. 1A and FIG. 1D, a circuit substrate 110 is provided. The circuit substrate 110 includes an insulating layer 120, circuit layers 130 and 130′, protective layers 140 and 140′, and a plurality of solder balls, such as a plurality of first solder balls 150 and a plurality of second solder balls 160. The circuit layer 130 is disposed on a first surface 120a of the insulating layer 120. The circuit layer 130′ is disposed on a second surface 120b of the insulating layer 120. The protective layer 140 is disposed on the circuit layer 130. The protective layer 140′ is disposed on the circuit layer 130′. The circuit layer 130 may include a dielectric layer 131 and a conductive layer 132. The circuit layer 130′ may include a dielectric layer 131′ and a conductive layer 132′. The protective layer 140 has a plurality of openings, such as a plurality of first openings 145 and a plurality of second openings 146, to expose the conductive layer 132 in the circuit layer 130. The first solder balls 150 are disposed on the protective layer 140 and embedded in the corresponding first openings 145, and first spaces 153 are formed between the first solder balls 150 and the protective layer 140. The second solder balls 160 are disposed on the protective layer 140 and embedded in the corresponding second openings 146, and second spaces 163 are formed between the second solder balls 160 and the protective layer 140.

In the embodiment, the insulating layer 120 may include a core layer, and the core layer may include a polymer glass fiber composite substrate, a glass substrate, a ceramic substrate, a silicon-on-insulator substrate, or a polyimide (PI) glass fiber composite substrate; the disclosure is not limited thereto. In other embodiments, the insulating layer 120 may be a dielectric layer having a single layer of a dielectric material or multiple layers of the dielectric material.

In the embodiment, if the insulating layer 120 is the core layer, a double sided wiring board may be formed by the insulating layer 120, the circuit layer 130 on the first surface 120a, and the circuit layer 130′ on the second surface 120b. Moreover, the insulating layer 120 can have a conductive through via 121 penetrating the first surface 120a and the second surface 120b such that the circuit layer 130 on the first surface 120a may be electrically connected to the circuit layer 130′ on the second surface 120b.

In the present embodiment, the dielectric layer 131 of the circuit layer 130 may be one layer or a plurality of layers, and/or the dielectric layer 131′ of the circuit layer 130′ may be one layer or a plurality of layers, and the invention is not limited thereto. Moreover, if the dielectric layers 131 and 131′ of the circuit layers 130 and 130′ are a plurality of layers, then the same or different materials or forming methods may be adopted between the plurality of dielectric layers 131 and 131′.

In the present embodiment, the conductive layers 132 of the circuit layer 130 may be one layer or a plurality of layers, and/or the conductive layers 132′ of the circuit layer 130′ may be one layer or a plurality of layers, and the invention is not limited thereto. Moreover, if the conductive layers 132 and 132′ of the conductive layers 130 and 130′ are a plurality of layers, then the same or different materials or forming methods may be adopted between the plurality of conductive layers 132 and 132′. In the case of the conductive layer 132 of the circuit layer 130, the conductive layers 132 having a multi-layer structure may be electrically connected to one another between the layers via at least one conductive via 133.

In other embodiments, a material of the insulating layer 120 is identical or similar to materials of the dielectric layers 131 and 131′ of the circuit layers 130 and 130′. That is, the insulating layer 120 may be a normal dielectric layer. Therefore, the circuit substrate 110 may be a coreless circuit board structure.

The protective layer 140 may be a dry film solder mask (DFSM) or a liquid photoimageable solder mask (LPSM). The protective layer 140′ may be a dry film solder mask or a liquid photoimageable solder mask. During the forming process of the solder balls 150 and/or the solder balls 160, the protective layer 140 can lower the probability of unexpected connection between two adjacent solder balls (such as between two solder balls 150, between two solder balls 160, and/or between a solder ball 150 and a solder ball 160).

The solder balls 150 and 160 may be provided on the protective layer 140 in one or a plurality of sizes. For example, in the embodiment, a plurality of first solder balls 150 and a plurality of second solder balls 160 are disposed on the protective layer 140, and the size of the first solder balls 150 is greater than the size of the second solder balls 160, but the invention is not limited thereto.

In general, the solder balls 150 and 160 may be formed by cooling to cure the molten metal solder. Therefore, portions 151 and 161 of the solder balls 150 and 160 protruding from a surface 140a of the protective layer 140 may substantially be spherical.

In the case of the first solder balls 150, the first solder balls 150 may include a bottom 152 and a spherical top 151 connected to each other. The bottom 152 is embedded in the corresponding first opening 145, and the shape of the bottom 152 corresponds to the shape of the first opening 145. The spherical top 151 is protruded outwardly from the first opening 145, and the spherical top 151 has a curved top surface 151a and a curved bottom surface 151b connected to each other. The curved bottom surface 151b faces the protective layer 140 such that the first spaces 153 are formed between the spherical top 151 and the protective layer 140.

In the case of the second solder balls 160, the second solder balls 160 may include a bottom 162 and a spherical top 161 connected to each other. The bottom 162 is embedded in the corresponding second opening 146, and the shape of the bottom 162 corresponds to the shape of the second opening 146. The spherical top 161 is protruded outwardly from the second opening 146, and the spherical top 161 has a curved top surface 161a and a curved bottom surface 161b connected to each other. The curved bottom surface 161b faces the protective layer 140 such that the second spaces 163 are formed between the spherical top 161 and the protective layer 140.

Next, refer to FIG. 1B. In the present embodiment, the circuit substrate 110 may be disposed on the carrier 10, and the solder balls 150 and 160 of the circuit substrate 110 may be away from the carrier 10. In some embodiments, the carrier 10 may be a carrier tape such as a blue tape, but the invention is not limited thereto.

Next, refer to FIG. 1C. In the present embodiment, a singulation process may be performed on the circuit substrate 110 (shown in FIG. 1B) on the carrier 10 to form a plurality of circuit substrates 110 shown in FIG. 1C. The singulation process includes, for instance, cutting the circuit substrate 110 (shown in FIG. 1B) via a blade, a wheel cutter, or a laser beam to form at least one trench 111 penetrating the circuit substrate 110, and the trench 111 exposes the carrier 10.

It should be mentioned that, after the singulation process is performed, similar reference numerals are used for the singulated elements. For example, the circuit substrate 110 (shown in FIG. 1B) may be a plurality of circuit substrates 110 (shown in FIG. 1C) after singulation, the insulating layer 120 (shown in FIG. 1B) may be a plurality of insulating layers 120 (shown in FIG. 1C) after singulation, the circuit layer 130 (shown in FIG. 1B) may be a plurality of circuit layers 130 (shown in FIG. 1C) after singulation, the circuit layer 130′ (shown in FIG. 1B) may be a plurality of circuit layers 130′ (shown in FIG. 1C) after singulation, the protective layers 140 (shown in FIG. 1B) may be a plurality of protective layers 140 (shown in FIG. 1C) after singulation, the protective layers 140′ (shown in FIG. 1B) may be a plurality of protective layers 140′ (shown in FIG. 1C) after singulation, the plurality of first solder balls 150 (shown in FIG. 1B) may be a plurality of first solder balls 150 (shown in FIG. 1C) after singulation, and the plurality of second solder balls 160 (shown in FIG. 1B) may be a plurality of second solder balls 160 (shown in FIG. 1C) after singulation . . . etc. The other singulated elements follow the same rules for reference numerals above and are not repeated herein.

Moreover, in the invention, the order of the singulation process is not limited. In other words, in other possible embodiments, a singulation process similar to the one shown in FIG. 1B to FIG. 1C can also be performed after any suitable subsequent step. Alternatively, in other possible embodiments, a plurality of circuit substrates 110 can also be directly disposed on the carrier 10 via a method similar to the one of FIG. 1C, and the plurality of circuit substrates 110 are isolated from one another to form the trenches 111 between the plurality of circuit substrates 110.

Next, refer to FIG. 1E and FIG. 1F. A photoresist material layer 171 is formed on the circuit substrate 110. A material of the photoresist material layer 171 may be a photoimageable molding compound. The photoresist material layer 171 covers the protective layer 140, the spherical top 151 of the first solder balls 150, and the spherical top 161 of the second solder balls 160. In other words, the photoresist material layer 171 is directly in contact with the surface 140a of the protective layer 140, the curved top surface 151a and the curved bottom surface 151b of the spherical top 151, and the curved top surface 161a and the curved bottom surface 161b of the spherical top 161. In other words, the photoresist material layer 171 is not only disposed on the protective layer 140, the first solder balls 150, and the second solder balls 160, but also filled in the first spaces 153 between the protective layer 140 and the first solder balls 150, and in the second spaces 163 between the protective layer 140 and the second solder balls 160.

In the present embodiment, the material of the photoresist material layer 171 may be a positive photoresist. In some embodiments, the material of the photoresist material layer 171 may further include barium titanate (BaTiO₃), boron nitride (BN), aluminum oxide, silicon dioxide, strontium titanate, barium strontium titanate, quartz, or other suitable fillers in addition to the positive photoresist.

In the present embodiment, if the singulation process shown in FIG. 1C has been performed before the photoresist material layer 171 is formed, the photoresist material layer 171 may be further filled in the trench 111.

Next, refer to FIG. 1G and FIG. 1H. After the photoresist material layer 171 (shown in FIG. 1E or FIG. 1F) is formed on the circuit substrate 110, an exposure process is performed on the photoresist material layer 171. In general, the portion of the positive photoresist irradiated by a corresponding light beam can be softened or decomposed during/after the exposure process. In other words, via the irradiation of the light beam L1 perpendicular to the surface 140a of the protective layer 140, a portion of the photoresist material layer 172 may be softened or decomposed. Specifically, in the direction perpendicular to the surface 140a of the protective layer 140, the portion of the photoresist material layer 171 filled in the first spaces 153 and the second spaces 163 is respectively shielded by the top 151 of the first solder balls 150 and the top 161 of the second solder balls 160. Therefore, the photoresist material layer 172 disposed on the curved top surfaces 151a and 161a and the curved top surfaces 151a and 161a may be softened or decomposed, and the portion of the photoresist material layer 171 filled in the first spaces 153 and the second spaces 163 is less readily softened or decomposed.

Next, refer to FIG. 1I and FIG. 1K. After the exposure process is performed, a developing process may be performed to remove a portion of the softened or decomposed photoresist material layer 172 (shown in FIG. 1G or FIG. 1H), which is outside the first spaces 153 and the second spaces 163 (shown in the FIG. 1G or FIG. 1H) and is softened or decomposed after being irradiated by the light L1 (shown in FIG. 1G). The curved top surfaces 151a of the first solder balls 150, the curved top surfaces 161a of the second solder balls 160, and a portion of the protective layer 140 are exposed after the developing process is performed.

In the present embodiment, another portion of the softened or decomposed photoresist material layer 172, which is in the trench 111 and is softened or decomposed after being irradiated by the light L1, may be further removed, and to expose the carrier 10.

Next, refer to FIG. 1I and FIG. 1K. After the developing process is performed, a curing process may be performed to cure the portion of the photoresist material layer 171 (shown in FIG. 1G or FIG. 1H) filled in the first spaces 153 and the second spaces 163. A dielectric layer 173 is formed between the first solder balls 150 and the protective layer 140 and between the second solder balls 160 and the protective layer 140. In other words, the dielectric layer 173 may also be referred to as a dielectric residual. The dielectric layer 173 surrounds the bases of the first solder balls 150 and the second solder balls 160 to achieve the effect of supporting and protecting the first solder balls 150 and the second solder balls 160, reducing the probability of drop ball of the first solder balls 150 and the second solder balls 160.

In the present embodiment, since the dielectric layer 173 is formed by curing the photoresist, the material of the dielectric layer 173 includes a photoimageable dielectric (PID).

After the above manufacturing process is performed, one or a plurality of circuit board elements 100 are substantially formed.

In the present embodiment, if the singulation process shown in FIG. 1C is performed in any step above, then after forming the dielectric layer 173, the carrier 10 on which the plurality of circuit board elements 100 are disposed may be removed to form the plurality of circuit board elements 100 shown in FIG. 1J.

Structurally, the circuit board element 100 of the present embodiment includes an insulating layer 120, circuit layers 130 and 130′, protective layers 140 and 140′, a plurality of first solder balls 150, a plurality of second solder balls 160, and a dielectric layer 173. The circuit layer 130 and the circuit layer 130′ are respectively disposed on two opposite sides of the insulating layer 120. The protective layer 140 is disposed on the circuit layer 130. The protective layer 140′ is disposed on the circuit layer 130′. The protective layer 140 has a plurality of first openings 145 and a plurality of second openings 146 exposing the circuit layer 130. The first solder balls 150 are disposed on the protective layer 140 and embedded in the corresponding first openings 145. The second solder balls 160 are disposed on the protective layer 140 and embedded in the corresponding second openings 146. The dielectric layer 173 is disposed between the first solder balls 150 and the protective layer 140 and between the second solder balls 160 and the protective layer 140.

In the present embodiment, in the direction perpendicular to the surface 140a of the protective layer 140, the orthographic projection of the dielectric layer 173 on the surface 140a of the protective layer 140 substantially overlaps and within the orthographic projection of the corresponding first solder balls 150 or second solder balls 160 on the surface 140a of the protective layer 140. In other words, in the direction perpendicular to the surface 140a of the protective layer 140, an edge 173c of the dielectric layer 173 may be aligned with an edge 151c of the top 151 of the corresponding first solder balls 150 (i.e., the section of the first solder balls 150 perpendicular to the surface 140a of the protective layer 140) or an edge 161c of the top 161 of the second solder balls 160 (i.e., the section of the second solder balls 160 perpendicular to the surface 140a of the protective layer 140).

In some possible embodiments, in the forming process of the dielectric layer 173, the orthographic projection of the dielectric layer 173 on the surface 140a of the protective layer 140 may slightly exceed the orthographic projection of the corresponding first solder balls 150 or second solder balls 160 on the surface 140a of the protective layer 140 due to slight deviation of the exposure process, a small amount of the photoresist material that should be removed in the developing process but is not fully removed, partial softening of the photoresist material in the curing process, or other hardly-controllable situations/conditions in the manufacturing process. However, the above-mentioned situations/conditions may be included in the foregoing “the orthographic projection of the dielectric layer 173 on the surface 140a of the protective layer 140 substantially overlaps and within the orthographic projection of the corresponding first solder balls 150 or second solder balls 160 on the surface 140a of the protective layer 140” or within an equivalent of the same or similar meaning.

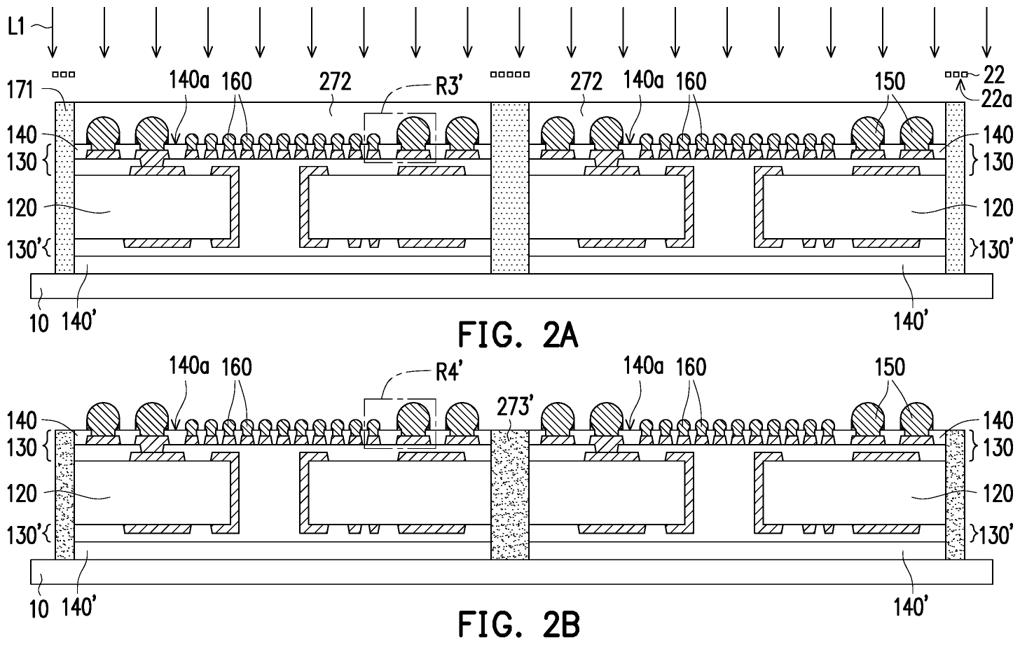

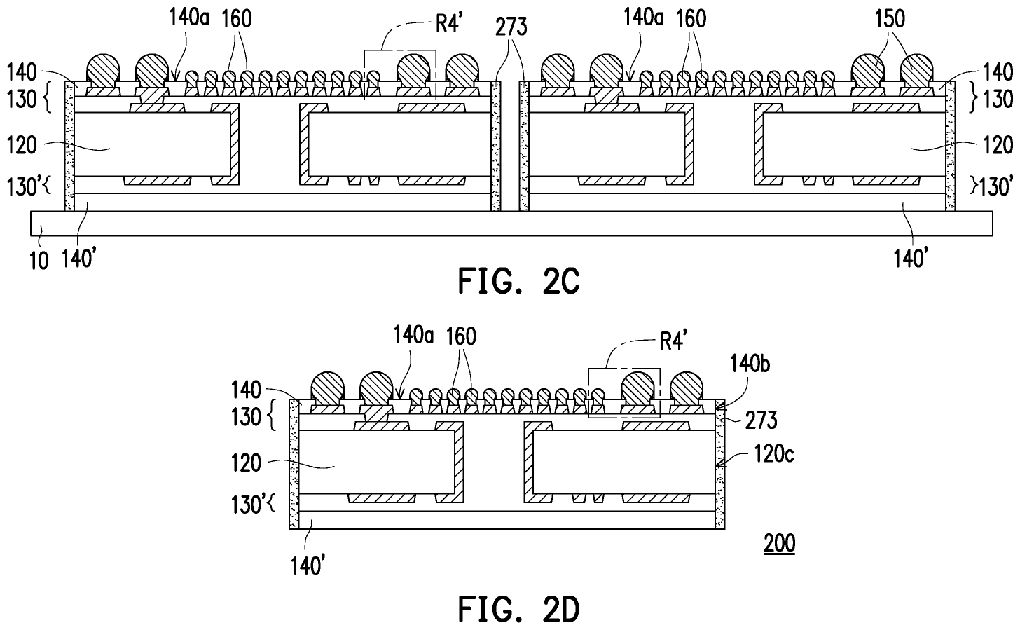

FIG. 2A to FIG. 2D are cross-sectional views of a portion of a manufacturing method of a circuit board element according to a second embodiment of the invention. The manufacturing method of a circuit board element 200 of the present embodiment is similar to the manufacturing method of the circuit board element 100 of the first embodiment, and similar members are represented by the same reference numerals and have similar function, material, or forming method, and are not repeated herein. Specifically, FIG. 2A to FIG. 2D show cross sections of a portion of the manufacturing method after the step in FIG. 1E. Moreover, the enlarged view of region R3′ in FIG. 2A may be the same as or similar to that of region R3 in FIG. 1H, and the enlarged view of region R4′ in FIG. 2B, FIG. 2C, or FIG. 2D may be the same as or similar to that of region R4 in FIG. 1K.

After the step in FIG. 1E, referring to FIG. 2A, the singulation process shown in FIG. 1C is first performed before the photoresist material layer 171 (shown in FIG. 1E or FIG. 1F) is formed. Moreover, after the photoresist material layer 171 is formed on the circuit substrate 110, an exposure process is performed on the photoresist material layer 171 via a mask 22. In the present embodiment, the material of the photoresist material layer 171 is a positive photoresist.

In the present embodiment, the region in which the mask 22 shields the light L1 is at least overlapped with the trench 111 (shown in FIG. 1C). In some embodiments not shown, in addition to being overlapped with the trench 111, the region in which the mask 22 shields the light L1 may also be overlapped with the first solder balls 150 and/or the second solder balls 160. In another embodiment, a plurality of slits 22a may be disposed in the portion of the mask 22 overlapped with the trench 111, a grayscale photomask is formed via a slit interference phenomenon, and the exposure depth of the light L1 in the trench 111 may be adjusted to only expose a portion of the photoresist material layer 171 at the top layer of the trench 111.

Next, refer to FIG. 2B. After the exposure process is performed, a developing process may be performed to remove the softened or decomposed photoresist material layer 272 (shown in FIG. 2A), which is outside the first spaces 153 and the second spaces 163 and is softened or decomposed after being irradiated by the light L1 (shown in FIG. 2A). The curved top surface 151a of the first solder balls 150, the curved top surface 161a of the second solder balls 160, and a portion of the protective layer 140 are exposed after the developing process is performed.

Next, refer to FIG. 2B. After the developing process is performed, a curing process may be performed to cure a portion of the photoresist material layer 171 (shown in FIG. 1H) filled in the first spaces 153 and the second spaces 163 and the portion of the photoresist material layer 171 (shown in FIG. 2A) filled in the trench 111.

In another embodiment, before or after the curing process, a portion of the photoresist material layer 171 (shown in FIG. 2A) at the top layer of the trench 111 may be thinned via a plasma etching process such that the top surface of a portion of a cured photoresist material layer 273′ and the top surface of the protective layer 140 are substantially coplanar, but the disclosure is not limited thereto.

Next, refer to FIG. 2C. After the curing process is performed, a portion of the cured photoresist material layer 273′ (shown in FIG. 2B) in the trench 111 may be removed, such as cutting a portion of the cured photoresist material layer 273′ in the trench 111 via a blade, a wheel cutter, or a laser beam to further form the dielectric layer 273 in the trench 111, and the trench 111 exposes the carrier 10.

After the process above, the manufacture of one or a plurality of circuit board elements 200 may be substantially completed. Moreover, the carrier 10 on which the plurality of circuit board elements 200 are disposed may be removed to form the plurality of circuit board elements 100 shown in FIG. 2D.

In terms of structure, the circuit board element 200 of the present embodiment is similar to the circuit board element 100 of the first embodiment, and the main difference is that in the dielectric layers 173 and 273 of the circuit board element 200, a portion of the dielectric layer 273 further covers a sidewall 120c of the insulating layer 120 and a sidewall 140b of the protective layer 140.

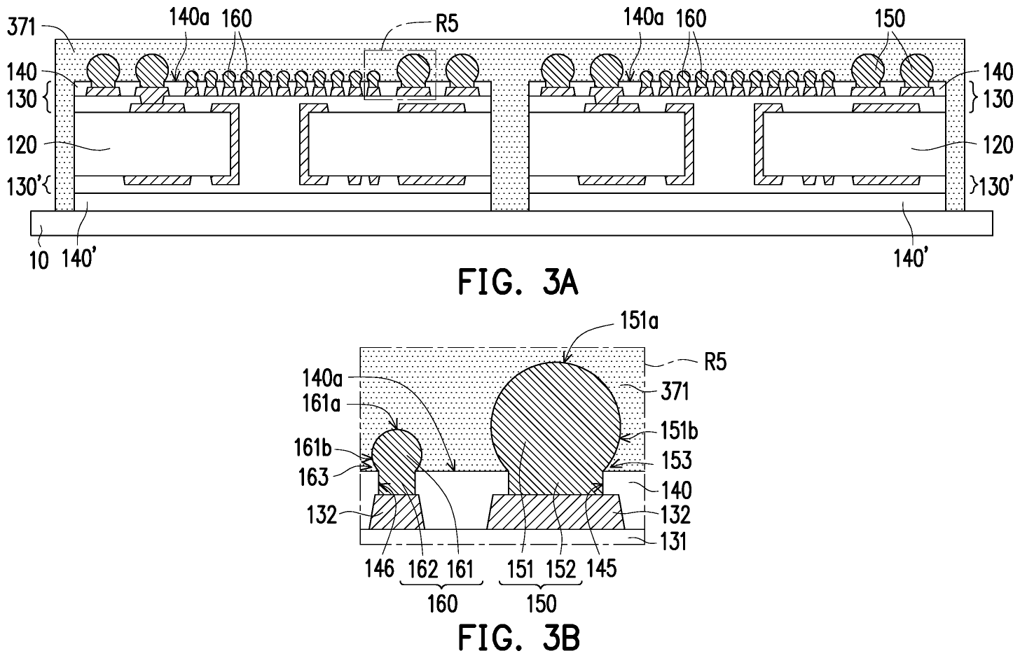

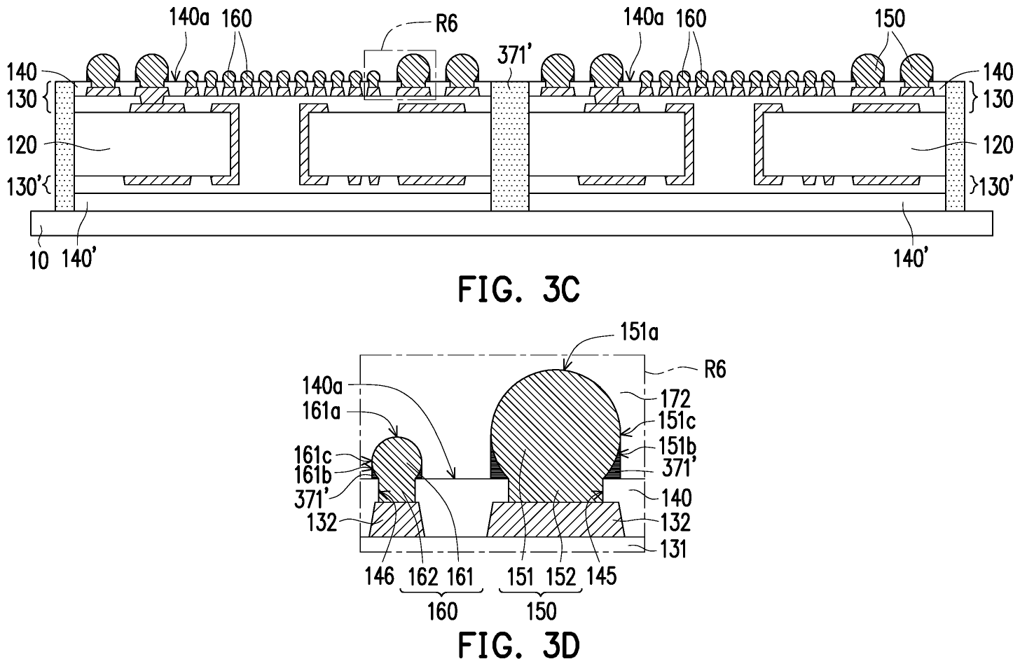

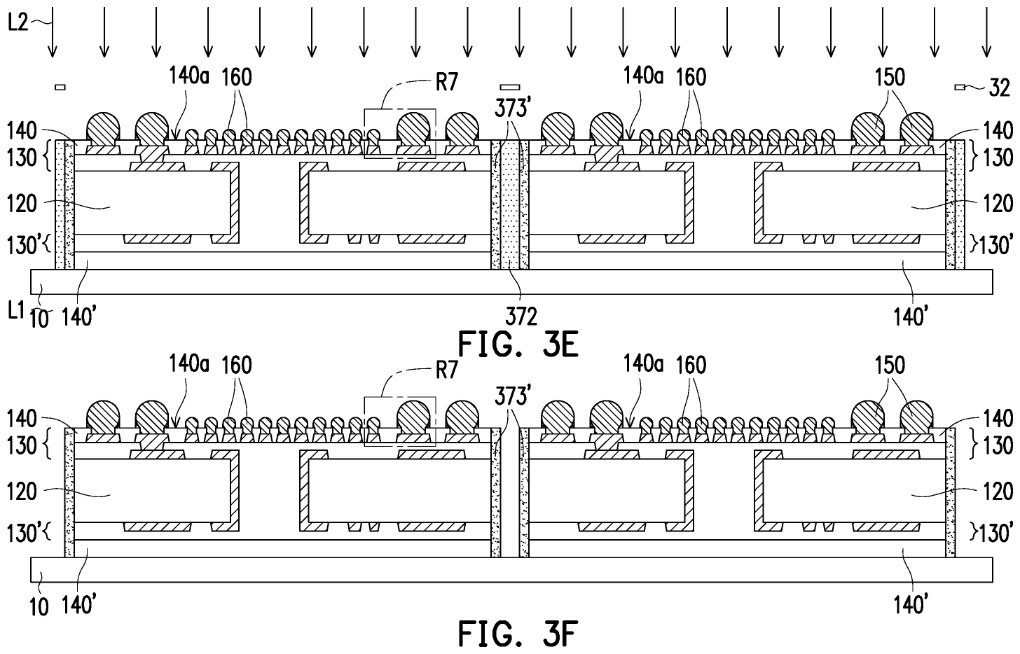

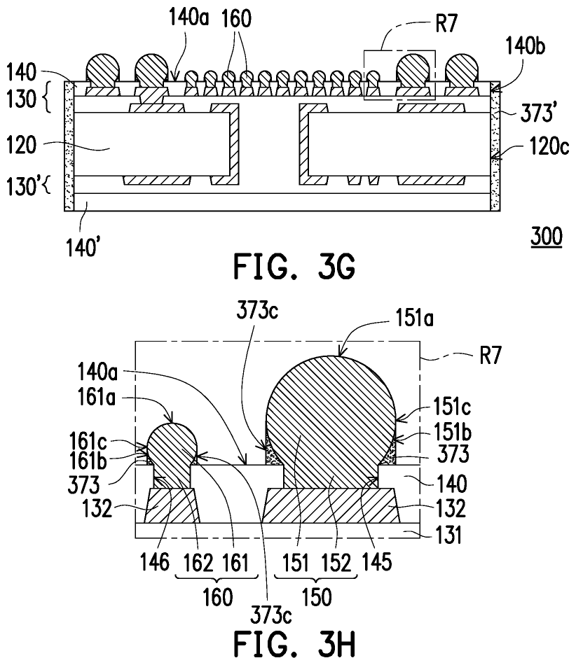

FIG. 3A to FIG. 3E are cross sections of a portion of the manufacturing method of a circuit board element according to the third embodiment of the disclosure. The manufacturing method of a circuit board element 300 of the present embodiment is similar to the manufacturing method of the circuit board element 100 of the first embodiment, and similar members are represented by the same reference numerals and have similar function, material, or forming method, and are not repeated herein. Specifically, FIG. 3A to FIG. 3E show cross sections of a portion of the manufacturing method of the circuit boar element 100 after the step of FIG. 1E. FIG. 3B may be an enlarged view of region R5 in FIG. 3A. FIG. 3D may be an enlarged view of region R6 in FIG. 3C. FIG. 3H may be an enlarged view of region R7 in FIG. 3E, FIG. 3F, or FIG. 3G.

After the step of FIG. 1C, referring to FIG. 3A and FIG. 3B, the singulation process shown in FIG. 1C is first performed before a photoresist material layer 371 is formed. Moreover, the photoresist material layer 371 is formed on the circuit substrate 110, and the photoresist material layer 371 may be further filled in the trench 111 (shown in FIG. 1C). The photoresist material layer 371 is directly in contact with the surface 140a of the protective layer 140, the curved top surface 151a of the spherical top 151, the curved bottom surface 151b of the spherical top 151, the curved top surface 161a of the spherical top 161, the curved bottom surface 161b of the spherical top 161, and the carrier 10 exposed by the trench 111 to cover the above. In other words, in addition to being located on the protective layer 140, the first solder balls 150, and the second solder balls 160 and filled in the trench 111, the photoresist material layer 371 is further filled in the first spaces 153 between the protective layer 140 and the first solder balls 150 and in the second spaces 163 between the protective layer 140 and the second solder balls 160.

In the present embodiment, the material of the photoresist material layer 371 may be a negative photoresist. Moreover, in some embodiments, in addition to the negative photoresist, the material of the photoresist material layer 371 may further include barium titanate, boron nitride, aluminum oxide, silicon dioxide, strontium titanate, barium strontium titanate, quartz, or other suitable fillers.

Next, refer to FIG. 3C and FIG. 3D. After the photoresist material layer 371 (shown in FIG. 3A or FIG. 3B) is formed on the circuit substrate 110, an anisotropic etching process is performed on the photoresist material layer 371 to remove a portion of the photoresist material layer 371 outside the first spaces 153 and the second spaces 163. Moreover, after the aforesaid anisotropic etching process, a photoresist material layer 371′ (shown in FIG. 3D) disposed on the surface 140a of the protective layer 140 may be disposed in the first spaces 153 and the second spaces 163 and may expose the curved top surface 151a of the first solder balls 150, the curved top surface 161a of the second solder balls 160, and a portion of the protective layer 140.

In the present embodiment, the anisotropic etching process is, for instance, a reactive-ion etching (RIE) process or a plasma etching process, but the disclosure is not limited thereto.

In the present embodiment, after the aforesaid anisotropic etching process, the photoresist material layer 371′ filled in the trench 111 may be coplanar with the surface 140a of the protective layer 140, but the disclosure is not limited thereto.

Next, refer to FIG. 3E. After the aforesaid anisotropic etching process, an exposure process is performed on the photoresist material layer 371′ (shown in FIG. 3C or FIG. 3D) via a mask 32 to cure the photoresist material layer 371′ irradiated by a light L2 to form dielectric layers 373 and 373′.

In the present embodiment, the exposure process is, for instance, a strong exposure process or a multiple exposure process (such as a double exposure process). Therefore, even in the direction perpendicular to the surface 140a of the protective layer 140, a portion of the photoresist material layer 371′(shown in FIG. 3D) filled in the first spaces 153 and the second spaces 163 is respectively shielded by the top 151 of the first solder balls 150 and the top 161 of the second solder balls 160, but may still be irradiated by scattered light of the light L2 or the light L2 slightly deviated from the direction perpendicular to the surface 140a of the protective layer 140 to form the dielectric layer 373.

In the present embodiment, the region in which the mask 32 shields the light L2 is at least not overlapped with the first solder balls 150 and the second solder balls 160. In some embodiments, the region in which the mask 32 shields the light L2 is also not overlapped with the sidewall of the trench 111, and a portion of the photoresist material layer 371′(shown in FIG. 3D) covering the sidewall of the trench 111 may form the dielectric layer 373′.

Next, refer to FIG. 3F. After the exposure process is performed, a developing process may be performed to remove the uncured photoresist material layer 372 (shown in FIG. 3E) in the trench 111 to expose a portion of the carrier 10.

After the process above, the manufacture of one or a plurality of circuit board elements 300 may be substantially completed.

In the present embodiment, the carrier 10 on which the plurality of circuit board elements 300 are disposed may be removed to form the plurality of circuit board elements 300.

In terms of structure, the circuit board element 300 of the present embodiment is similar to the circuit board element 200 of the second embodiment, with the main difference being that the material forming the dielectric layers 373 and 373′ may be a negative photoresist. In other words, the material of the dielectric layers 373 and 373′ includes a PID.

Specifically, the circuit board element 100 of the present embodiment includes an insulating layer 120, circuit layers 130 and 130′, protective layers 140 and 140′, a plurality of first solder balls 150, a plurality of second solder balls 160, and a dielectric layer 373. The dielectric layer 373 is disposed between the first solder balls 150 and the protective layer 140 and between the second solder balls 160 and the protective layer 140.

In the embodiment, in the direction perpendicular to the surface 140a of the protective layer 140, the orthographic projection of the dielectric layer 373 on the surface 140a of the protective layer 140 substantially overlaps and within the orthographic projection of the corresponding first solder balls 150 or second solder balls 160 on the surface 140a of the protective layer 140. In other words, in the direction perpendicular to the surface 140a of the protective layer 140, an edge 373c of the dielectric layer 373 may be aligned with an edge 151c of the top 151 of the corresponding first solder balls 150 or an edge 161c of the top 161 of the second solder balls 160.

In some possible embodiments, during the forming process of the dielectric layer 373, the orthographic projection of the dielectric layer 373 on the surface 140a of the protective layer 140 may slightly exceed the orthographic projection of the corresponding first solder balls 150 or second solder balls 160 on the surface 140a of the protective layer 140 due to slight deviation of the exposure process, a small amount of the photoresist material that should be removed in the developing process but is not removed, or partial softening of the photoresist material in the curing process, but the above situations do not depart from the spirit of the disclosure and may be within “the orthographic projection of the dielectric layer 373 on the surface 140a of the protective layer 140 substantially overlaps and within the orthographic projection of the corresponding first solder balls 150 or second solder balls 160 on the surface 140a of the protective layer 140” or an equivalent of the same or similar meaning.

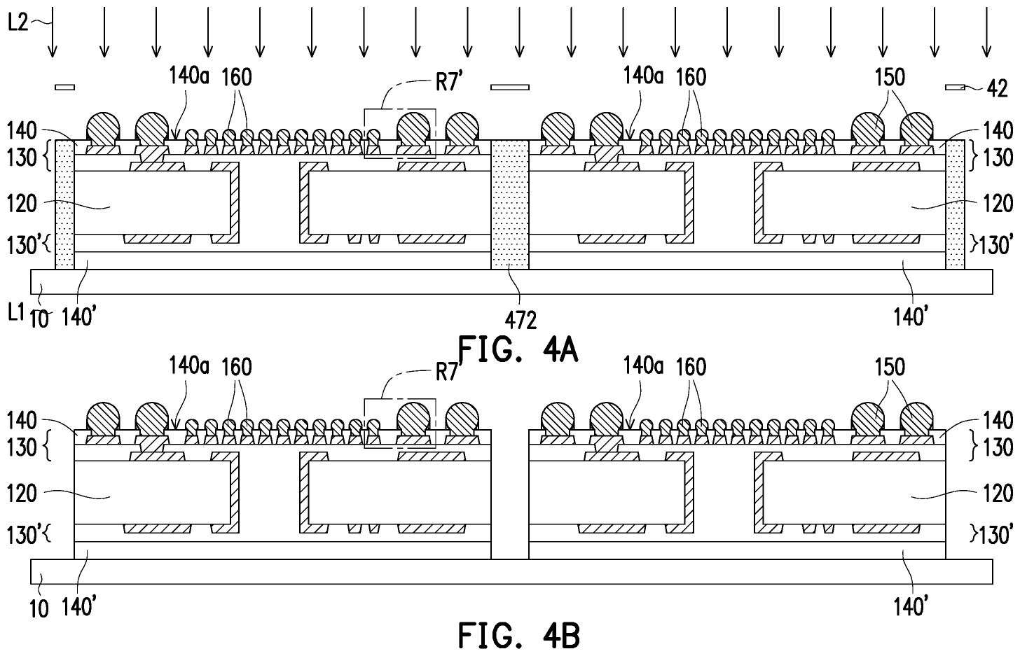

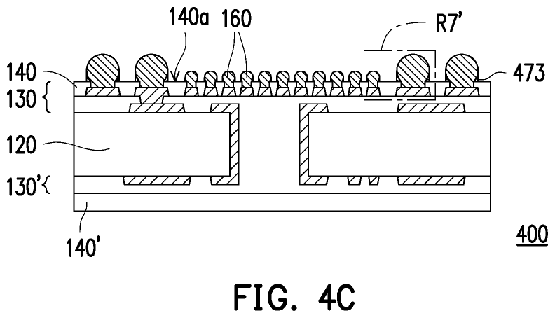

FIG. 4A to FIG. 4C are cross-sectional views of a portion of a manufacturing method of a circuit board element according to a fourth embodiment of the invention. The manufacturing method of a circuit board element 400 of the present embodiment is similar to the manufacturing method of the circuit board element 300 of the third embodiment, and similar members are represented by the same reference numerals and have similar function, material, or forming method, and are not repeated herein. Specifically, FIG. 4A to FIG. 4C show cross sections of a portion of the manufacturing method of the circuit boar element 300 after the step of FIG. 3C. Moreover, the enlarged view of region R7′ in FIG. 4A, FIG. 4B, or FIG. 4C may be the same as or similar to that of region R7 in FIG. 3H.

After the step of FIG. 3C, referring to FIG. 4A, after the aforesaid anisotropic etching process, an exposure process is performed on the photoresist material layer 371′ (shown in FIG. 3C or FIG. 3D) via a mask 42 to cure the photoresist material layer 371′ irradiated by a light L2 to form dielectric layers 373. In the present embodiment, the material of the photoresist material layer 371371′ may be a negative photoresist.

In the present embodiment, the region in which the mask 42 shields the light L2 is at least not overlapped with the first solder balls 150 and the second solder balls 160 and is completely overlapped with the trench 111. In other words, the photoresist material layer 472 in the trench 111 is not irradiated by the light L2 and is not cured.

In the present embodiment, the exposure process shown in FIG. 4A may be the same as or similar to the exposure process shown in FIG. 3C.

Next, refer to FIG. 4B. After the exposure process is performed, a developing process may be performed to remove the uncured photoresist material layer 472 (shown in FIG. 4A) in the trench 111 (shown in FIG. 1C) to expose a portion of the carrier 10.

After the process above, the manufacture of one or a plurality of circuit board elements 400 may be substantially completed.

In the present embodiment, the carrier 10 on which the plurality of circuit board elements 400 are disposed may be removed to form the plurality of circuit board elements 400.

In terms of structure, the circuit board element 400 of the present embodiment is similar to the circuit board element 100 of the first embodiment, with the main difference being that the material forming the dielectric layers 473 may be a negative photoresist. In other words, the material of the dielectric layers 473 includes a PID.

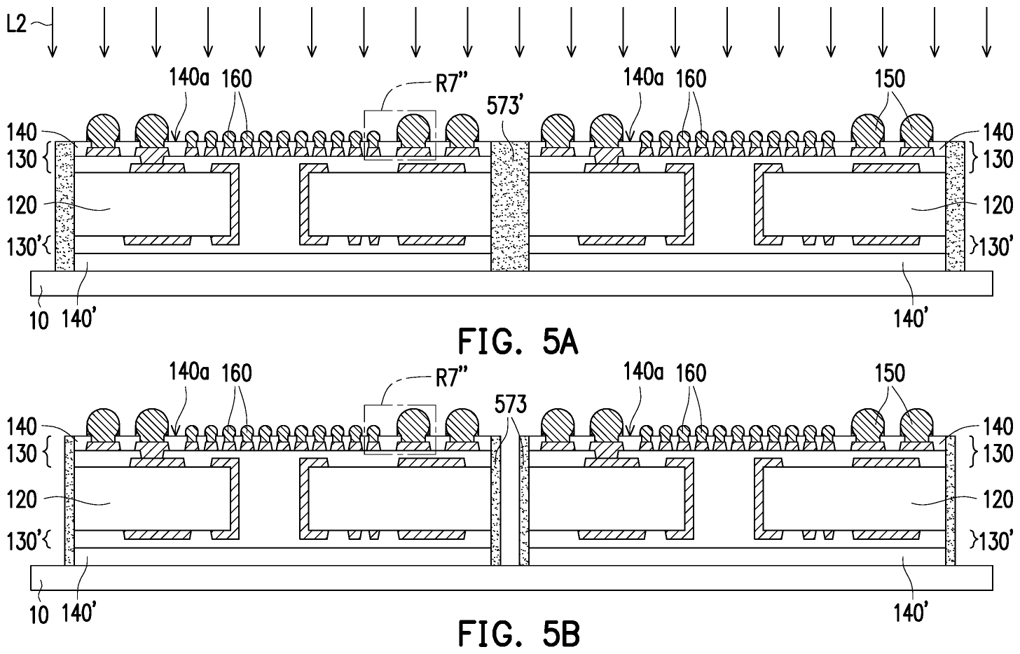

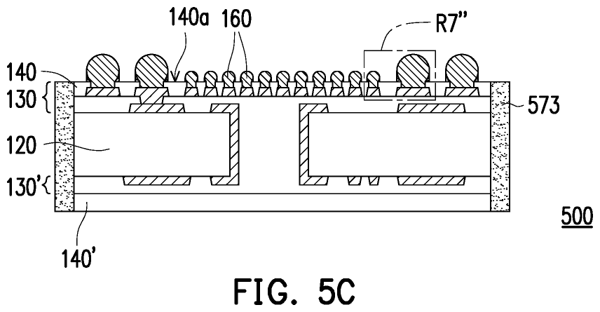

FIG. 5A to FIG. 5C are cross-sectional views of a portion of a manufacturing method of a circuit board element according to a fifth embodiment of the invention. The manufacturing method of a circuit board element 500 of the present embodiment is similar to the manufacturing method of the circuit board element 300 of the third embodiment, and similar members are represented by the same reference numerals and have similar function, material, or forming method, and are not repeated herein. Specifically, FIG. 5A to FIG. 5C show cross sections of a portion of the manufacturing method of the circuit boar element 500 after the step of FIG. 3C. Moreover, the enlarged view of region R7″ in FIG. 5A, FIG. 5B, or FIG. 5C may be the same as or similar to that of region R7 in FIG. 3H.

After the step of FIG. 3C, referring to FIG. 5A, after the aforesaid anisotropic etching process, an exposure process is performed on the photoresist material layer 371′ (shown in FIG. 3C or FIG. 3D). In the present embodiment, the exposure process is, for instance, a strong exposure process or a multiple exposure process (such as a double exposure process). The photoresist material layer 371′ in the first spaces 153, the second spaces 163, and the trench 111 (shown in FIG. 1C) is cured.

In the present embodiment, the exposure process shown in FIG. 5A is similar to the exposure process shown in FIG. 3C, with the main difference being that no mask is used in the exposure process shown in FIG. 5A. Therefore, a portion of the photoresist material layer 371′ disposed in the trench 111 may be irradiated with the light L2 to form a cured photoresist material layer 573′.

Next, refer to FIG. 5B. After the curing process is performed, a portion of the cured photoresist material layer 573′ (shown in FIG. 5A) in the trench 111 may be cut or removed, such as cutting a portion of the cured photoresist material layer 273′ in the trench 111 via a blade, a wheel cutter, or a laser beam to form the dielectric layer 573, and the trench 111 exposes the carrier 10.

After the process above, the manufacture of one or a plurality of circuit board elements 500 may be substantially completed.

In the present embodiment, the carrier 10 on which the plurality of circuit board elements 500 are disposed may be removed to form the plurality of circuit board elements 500 as shown in FIG. 5C.

The circuit board element 500 of the present embodiment is the same as or similar to the circuit board element 300 of the third embodiment in structure or material. Specifically, the dielectric layer 573 in the circuit board element 500 may be the same as or similar to the dielectric layer 373′ in the circuit board element 300 in structure or material.

Based on the above, in the disclosure, a dielectric layer is formed between the solder balls and the protective layer by photoresist. The dielectric layer between the solder balls and the protective layer may be directly in contact with a curved bottom surface of a spherical top of the solder balls to support or fix the spherical top of the solder balls. In other words, the dielectric layer between the solder balls and the protective layer may also be referred to as a dielectric block surrounding a base of the solder balls to achieve the effect of supporting and protecting the solder balls. Therefore, the probability of solder ball detachment may be reduced such that the yield of the circuit board element may be improved. Moreover, even if the plurality of solder balls have different sizes, the dielectric layers between the protective layer and the solder balls of different sizes can have different sizes by the manufacturing method of the disclosure. As a result, even if the plurality of solder balls have different sizes, the probability of detachment of the plurality of solder balls may be reduced via the corresponding dielectric layer, and electrical connection with other electronic elements is not affected by the dielectric layers having the same size or height between solder balls having different sizes and the protective layer.

Although the disclosure has been described with reference to the above embodiments, it will be apparent to one of ordinary skill in the art that modifications to the described embodiments may be made without departing from the spirit of the disclosure. Accordingly, the scope of the disclosure is defined by the attached claims not by the above detailed descriptions.

What is claimed is:

1. A manufacturing method of a circuit board element, comprising:
providing a circuit substrate, the circuit substrate comprising:
an insulating layer;
a circuit layer disposed on the insulating layer;
a protective layer disposed on the circuit layer and having a plurality of openings exposing the circuit layer; and
a plurality of solder balls disposed on the protective layer and embedded in the corresponding openings, and a space is formed between each of the solder balls and the protective layer;
placing the circuit substrate on a carrier, and the solder balls are away from the carrier;
forming at least one trench penetrating the circuit substrate to expose the carrier;
forming a photoresist material layer on the circuit substrate to cover the circuit substrate and filling the spaces, and the photoresist material layer is filled in the at least one trench to cover the carrier;
curing a portion of the photoresist material layer filled in the spaces to form a dielectric layer between the solder balls and the protective layer;
removing a portion of the photoresist material layer filled in the at least one trench to expose the carrier; and
removing the carrier.

2. The manufacturing method of the circuit board element of claim 1, wherein a material of the photoresist material layer comprises a photoresist and a filler.

3. The manufacturing method of the circuit board element of claim 1, wherein a material of the photoresist material layer comprises a positive photoresist, and the manufacturing method further comprises:
performing an exposure and a developing process on the photoresist material layer before the dielectric layer is formed to remove a portion of the photoresist material layer not filled in the spaces and expose the solder balls and a portion of the protective layer.

4. The manufacturing method of the circuit board element of claim 1, wherein a material of the photoresist material layer comprises a positive photoresist, and the manufacturing method further comprises:
performing an exposure and a developing process on the photoresist material layer before the dielectric layer is formed to remove a portion of the photoresist material layer not filled in the spaces and expose the solder balls, a portion of the protective layer, and the carrier corresponding to the trench.

5. The manufacturing method of the circuit board element of claim 1, wherein a material of the photoresist material layer comprises a positive photoresist, and the manufacturing method further comprises:
performing an exposure and a developing process on the photoresist material layer via a mask before the dielectric layer is formed to remove a portion of the photoresist material layer and expose the solder balls and a portion of the protective layer;
curing the portion of the photoresist material layer filled in the spaces and covering a sidewall of the trench to form the dielectric layer.

6. The manufacturing method of the circuit board element of claim 5, wherein the mask has a plurality of slits.

7. The manufacturing method of the circuit board element of claim 1, wherein a material of the photoresist material layer comprises a negative photoresist, and the manufacturing method further comprises:
performing an anisotropic etching process on the photoresist material layer before the dielectric layer is formed to remove a portion of the photoresist material layer to expose the solder balls and a portion of the protective layer.

8. The manufacturing method of the circuit board element of claim 1, wherein a material of the photoresist material layer comprises a negative photoresist, and the manufacturing method further comprises:
performing an anisotropic etching process on the photoresist material layer before the dielectric layer is formed to remove a portion of the photoresist material layer not filled in the spaces and expose the solder balls and a portion of the protective layer; and
performing an exposure process on the photoresist material layer via a mask to cure the portion of the photoresist material layer filled in the spaces to form the dielectric layer.

9. The manufacturing method of the circuit board element of claim 8, wherein the exposure process further cures a portion of the photoresist material layer covering a sidewall of the at least one trench to form the dielectric layer.

10. The manufacturing method of the circuit board element of claim 1, wherein a material of the photoresist material layer comprises a negative photoresist, and the manufacturing method further comprises:
performing an anisotropic etching process on the photoresist material layer before the dielectric layer is formed to remove a portion of the photoresist material layer not filled in the spaces and expose the solder balls and a portion of the protective layer;
performing an exposure process on the photoresist material layer to cure another portion of the photoresist material layer filled in the spaces and filled in the at least one trench; and
removing a portion of the cured photoresist material layer filled in the at least one trench to form the dielectric layer.

11. The manufacturing method of the circuit board element of claim 1, wherein a method of removing the portion of the cured photoresist material layer filled in the at least one trench comprises cutting.

12. A circuit board element, comprising:
an insulating layer;
a circuit layer disposed on the insulating layer;
a protective layer disposed on the circuit layer and having a plurality of openings exposing the circuit layer; and
a plurality of solder balls disposed on the protective layer and embedded in the corresponding openings; and
a dielectric layer disposed between the solder balls and the protective layer.

13. The circuit board element of claim 12, wherein the insulating layer comprises a core layer.

14. The circuit board element of claim 13, wherein a material of the core layer is different from a material of the protective layer and a material of the dielectric layer, the material of the core layer comprises a polymer glass fiber composite material substrate, a glass substrate, a ceramic substrate, an insulating silicon substrate, or a polyimide glass fiber composite substrate.

15. The circuit board element of claim 12, wherein a material of the dielectric layer comprises a photoimageable dielectric.

16. The circuit board element of claim 15, wherein the material of the dielectric layer further comprises a filler.

17. The circuit board element of claim 12, wherein an orthographic projection of the dielectric layer on the protective layer is overlapped with an orthographic projection of the solder balls on the protective layer.

18. The circuit board element of claim 12, wherein an edge of the dielectric layer is aligned with an edge of the solder balls.

19. The circuit board element of claim 12, wherein the dielectric layer further covers a sidewall of the insulating layer and a sidewall of the protective layer.

20. The circuit board element of claim 12, wherein the solder balls comprise a plurality of first solder balls and a plurality of second solder balls, a size of the first solder balls is greater than a size of the second solder balls, and a size of the dielectric layer between the first solder balls and the protective layer is greater than a size of the dielectric layer between the second solder balls and the protective layer.
